(19) United States
(12) Patent Application Publication
(10) Pub. No.: US 2024/0404841 A1
(43) Pub. Date: Dec. 5, 2024

(54) FACTORY INTERFACE VACUUM GENERATION USING VACUUM EJECTORS

(71) Applicant: Applied Materials, Inc., Santa Clara, CA (US)

(72) Inventors: Praveen A. KOTINATOT, Bangalore (IN); Preetham SUDHEENDRA, Bangalore (IN); Venkatraman GANESAN, Bangalore (IN)

(21) Appl. No.: 18/204,490

(22) Filed: Jun. 1, 2023

(51) Int. Cl. H01L 21/67; B65G 47/91

(52) U.S. Cl. CPC H01L 21/67017; B65G 47/91; H01L 21/67196; H01L 21/67201; H01L 21/67242

(57) ABSTRACT

A system operable for transporting semiconductor substrates includes a factory interface. The system further includes one or more robots disposed within the factory interface. The system further includes a vacuum ejector operable to provide vacuum to the factory interface.

### BACKGROUND

### Field

Embodiments disclosed herein generally relate to providing vacuum to a factory interface (FI) within a processing system operable for transporting semiconductor substrates.

### Description of Related Art

Electronic device manufacturing systems may include multiple process chambers arranged around a mainframe housing having a transfer chamber and one or more load lock chambers configured to pass substrates into the transfer chamber. The process chambers as well as the transfer chamber can each be held at vacuum. These systems may employ a transfer robot, which may be housed in the transfer chamber, for example. The transfer robot may be a selectively compliant articulated robot arm (SCARA) robot or the like, and may be adapted to transport substrates between the various chambers and one or more load lock chambers. For example, the transfer robot may transport substrates from process chamber to process chamber, from load lock chamber to process chamber, and vice versa.

Processing of substrates in semi-conductor component manufacturing is generally carried out in multiple tools, where the substrates travel between the tools in substrate carriers (e.g., Front Opening Unified Pods or FOUPs). The FOUPs may be docked to a factory interface (FI) (sometimes referred to as an equipment front-end module (EFEM)), which includes a load/unload robot therein that is operable to transfer substrates between the FOUPs and the one or more load locks of the tools, therefore allowing pass-through of substrates for processing. Existing systems may benefit from efficiency and/or process quality improvements.

Therefore, there is a need for improved apparatus and methods for providing vacuum for factory interfaces within processing systems operable for transporting semiconductor substrates.

### SUMMARY

The present disclosure generally relates to providing vacuum to a factory interface (FI) within a processing system operable for transporting semiconductor substrates, including providing vacuum to a factory interface using clean dry air (CDA) operated vacuum ejectors.

In an embodiment, a method for providing vacuum to a factory interface includes receiving data regarding vacuum provided to the factory interface and causing a vacuum ejector to provide vacuum to the factory interface. The factory interface is within a processing system operable for transporting semiconductor substrates. The data is received from one or more sensors. Causing the vacuum ejector to provide vacuum to the factory interface is based on the data.

In an embodiment, a system operable for transporting semiconductor substrates includes a factory interface, one or more robots, and a vacuum ejector. The one or more robots are disposed within the factory interface. The vacuum ejector is operable to provide vacuum to the factory interface.

In an embodiment, a system operable for transporting substrates includes a factory interface (FI), a first robot, a sensor, a vacuum ejector, a source of clean dry air (CDA), a CDA regulator, a load lock, a first door, a vacuum pump, a transfer chamber, a second robot disposed, one or more processing chambers, and a controller. The FI has one or more load ports. The first robot is disposed within the FI. The sensor is operable to generate a signal based on a condition associated with the FI. The vacuum ejector is operable to provide vacuum to the FI. The CDA regulator is operable to control a flow of the CDA from the source to the vacuum ejector. The first door is operable to open and close. An interior of the load lock and the interior of the FI are in fluidic communication while the first door is open. The interior of the load lock is fluidically isolated from the interior of the FI while the first door is closed. The vacuum pump is operable to remove gas from the interior of the load lock. The interior of the FI is fluidically isolated from the vacuum pump while the first door is closed. The second robot is disposed within the transfer chamber. The controller is configured to cause the first robot to receive a carrier with a substrate thereon from one of the load ports. The controller is also configured to cause the vacuum ejector to provide vacuum to the FI after the first robot receives the carrier with the substrate. The controller is also configured to cause the first door to open after the vacuum ejector provides vacuum to the FI. The controller is also configured to cause the first robot to place the carrier with the substrate into the load lock while the first door is open. The controller is also configured to cause the first door to close after the first robot places the carrier with the substrate into the load lock. The controller is also configured to cause the vacuum pump to remove gas from the load lock after the first door closes.

### BRIEF DESCRIPTION OF THE DRAWINGS

So that the manner in which the above-recited aspects are attained and can be understood in detail, a more particular description of embodiments described herein, briefly summarized above, may be had by reference to the appended drawings. It is to be noted, however, that the appended drawings illustrate typical embodiments and are therefore not to be considered limiting; other equally effective embodiments are contemplated.

FIG. 1 is a schematic top view of a substrate processing system including environmental control of a factory interface (FI) chamber and including an FI filter purge capability, according to one embodiment.

FIG. 2 is a first partial, cross-sectional, side view of a substrate processing system including FI filter purge capability, according to one embodiment.

FIG. 3 is another partial, cross-sectional, side view of a substrate processing system including FI filter purge capability, according to one embodiment.

FIG. 4 is a schematic diagram of a system for transporting substrates including a vacuum source for an FI, according to a previously known embodiment.

FIG. 5 is another schematic view of a system for transporting substrates including a vacuum source for an FI, according to one embodiment.

FIG. 6 illustrates two graphs of performance of a vacuum ejector, according to one embodiment.

FIG. 7 is a flowchart of a method for providing vacuum to an FI within a processing system operable for transporting semiconductor substrates.

### DETAILED DESCRIPTION

The present disclosure relates generally to providing vacuum to a factory interface (FI) within a processing system operable for transporting semiconductor substrates. More specifically, embodiments disclosed herein are related to systems using vacuum ejectors to supply vacuum to an FI of a substrate processing system.

Providing vacuum to an FI is desirable because of the several uses for vacuum in the FI. For example, doors of Front Opening Unified Pods (FOUPs) can be opened by controlling vacuum supplied to actuators, aligners used for substrate clamping can be vacuum actuated, and robot blades used for substrate clamping can be vacuum actuated. Using vacuum ejectors to supply vacuum to an FI offers a number of advantages. First, using vacuum ejectors to supply vacuum to the FI enables designs for FIs that do not include a connection to a vacuum pump, i.e., instead of a connection to a vacuum pump and a connection to a clean dry air (CDA) supply, as in typical FIs. An FI that does not include a connection to a vacuum pump reduces the piping, wiring, and control systems of the FI. Reducing the piping and wiring to an FI reduces the capital costs of a substrate processing system including such an FI. Second, an FI that does not include a connection to a vacuum pump reduces operating and maintenance costs, as compared to a typical FI. Thus, a substrate processing system including such an FI results in lower operating and maintenance costs.

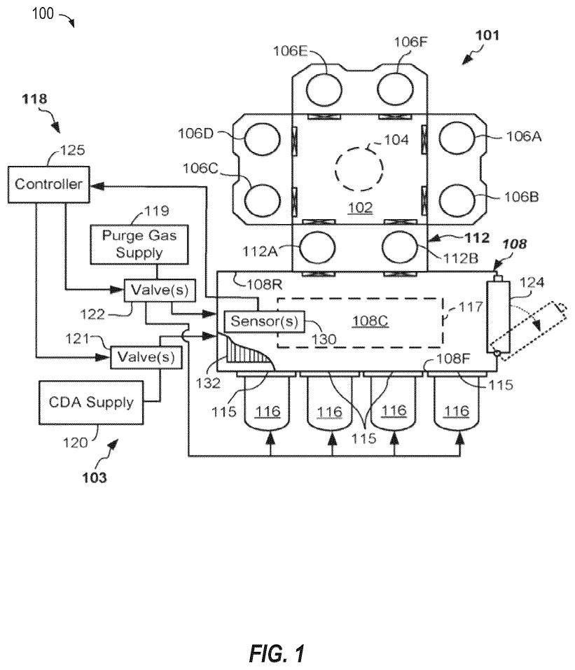

FIGS. 1-3 illustrate schematic diagrams of an example embodiment of a substrate processing system 100 according to one or more embodiments of the present disclosure. The substrate processing system 100 may include a processing portion 101 configured to process substrates 245. The processing portion 101 can include mainframe housing having housing walls defining a transfer chamber 102. A transfer robot 104 (shown as a dotted circle in FIG. 1) may be at least partially housed within the transfer chamber 102. The transfer robot 104 may be configured and adapted to place or extract substrates 245 to and from process chambers 106A-106F via its operation. Substrates as used herein refers to articles used to make electronic devices or circuit components, such as silica-containing discs or wafers, patterned or masked wafers, glass plates, or the like.

Transfer robot 104, in the depicted embodiment, may be any suitable type of robot adapted to service the various chambers (such as twin chambers shown) coupled to and accessible from the transfer chamber 102.

The transfer chamber 102 in the depicted embodiment may be generally square or rectangular in shape. However, other suitable shapes of the mainframe housing and numbers of facets and processing chambers are possible, such as octagonal, hexagonal, heptagonal, octagonal, and the like. The destinations for the substrates may be one or more of the process chambers 106A-106F, which may be configured and operable to carry out one or more processes on the substrates delivered thereto. The processes carried out by process chambers 106A-106F may be any suitable process such as plasma vapor deposition (PVD), chemical vapor deposition (CVD), etching, annealing, pre-cleaning, metal removal, metal oxide removal, or the like. Other processes may be carried out on substrates 245 therein.

The substrate processing system 100 can further include a factory interface 108 that includes environmental controls. Substrates 245 may be received into the transfer chamber 102 from the factory interface 108, and also exit the transfer chamber 102 to the factory interface 108 after processing thereof. Entry and exit to the transfer chamber 102 may be through an opening, or if a vacuum tool, through a load lock 112 that is coupled to a wall (e.g., a rear wall 108R) of the factory interface 108. The load lock 112 may include one or more load lock chambers (e.g., load lock chambers 112A, 112B, for example). Load lock chambers 112A, 112B included in the load lock 112 may be single wafer load locks (SWLL) chambers, or multi-wafer load lock chambers, or even batch load locks, and the like.

The factory interface 108 may be any suitable enclosure, and may have side walls (that may include the rear wall 108R, a front wall 108F opposite the rear wall 108R, two side walls, a top, and a bottom) forming a factory interface chamber 108C. One or more of the walls, such as side walls can include an access door 124 allowing servicing personnel to access the factory interface chamber 108C when a component within the factory interface chamber 108C is being serviced (repaired, changed, cleaned, or the like).

One or more load ports 115 may be provided on one or more of the walls (e.g., front wall 108F) of the factory interface 108 and may be configured and adapted to receive one or more substrate carriers 116 (e.g., FOUPs or the like). Factory interface chamber 108C may include a load/unload robot 117 (shown as a dotted box in FIG. 1) of conventional construction. Load/unload robot 117 may be configured and operational, once the carrier doors 216D of the substrate carriers 116 are opened, to extract substrates 245 from the one or more substrate carriers 116 and feed the substrates 245 through the factory interface chamber 108C and into one or more openings (e.g., the one or more load lock chambers 112A, 112B). Any suitable construction of the opening allowing transfer of substrates 245 between the factory interface chamber 108C and the process chambers 106A-106F can be used. Any number of processing chambers and configurations thereof can be used.

In some vacuum embodiments, the transfer chamber 102 may include slit valves at an ingress/egress to the various process chambers 106A-106F. Likewise, load lock chambers 112A, 112B in the load lock 112 may include inner load lock slit valves 223i and outer load lock slit valves 223o. Slit valves 223o, 223i are adapted to open and close when placing or extracting substrates 245 to and from the various process chambers 106A-106F and load lock chambers 112A, 112B. Slit valves 223o, 223i may be of any suitable conventional construction, such as L-motion slit valves. For example, slit valves 223o and 223i may each include a door operable to open and shut, such that opening and closing each slit valve includes opening and closing a corresponding door.

In the depicted embodiment, a factory interface environmental control apparatus 118 is provided. Factory interface environmental control apparatus 118 can provide environmental control of the gaseous environment within the factory interface chamber 108C by providing an environmentally-controlled atmosphere thereto during transfer of substrates 245 through the factory interface chamber 108C. In particular, factory interface environmental control apparatus 118 is coupled to the factory interface 108 and operational to monitor and/or control one or more environmental conditions within the factory interface chamber 108C.

In some embodiments, and at certain times, the factory interface chamber 108C may receive a purge gas therein. For example, the purge gas can be an inert gas, such as Argon (Ar), Nitrogen (N₂), or helium (He). The purge gas can be supplied from a purge gas supply 119. Purge gas supply 119 may be coupled to the factory interface chamber 108C by any suitable means such as one or more conduits including valves 122, such as an on-off valve or mass flow controller therein. However, in some embodiments, where exposure of the substrate 245 to O₂ is not a major concern, the purge gas can be clean dry air, such as provided from a clean dry air supply 120. Clean dry air as used herein is defined as air that is dry and contains few particulates. Clean dry air can include particulates no larger than 2 microns and can have a relatively lower relative humidity level as compared to ambient air in the factory environment outside of the factory interface chamber 108C. In particular, by one suitable measure, clean dry air can have a relative humidity level of 10% or less at room temperature. Further, clean dry air can have a relative humidity level of 5% or less at room temperature. In some embodiments, the clean dry air can be ultra clean dry air having less than 500 parts per million volumetric (ppmV) of H₂O, less than 100 ppmV of H₂O, or even less than 10 ppmV of H2O therein. In some embodiments, clean dry air can have particulates no larger than 0.05 microns.

In more detail, the factory interface environmental control apparatus 118 may control at least one of the following within the environment within the factory interface chamber 108C:
1) relative humidity level (% RH at room temperature),
2) temperature (T),
3) an amount of O₂,
4) an amount of inert gas,
5) an amount of clean dry air,
6) an amount of chemical contaminant (e.g., amines, bases, an amount of one or more volatile organic compound (VOC), or the like),
7) chamber pressure within the factory interface chamber 108C, or
8) gas flow rate to or from the factory interface chamber 108C.

Other environmental conditions of the factory interface chamber 108C may be monitored and/or controlled, such as gas flow rate to or from the factory interface chamber 108C, chamber pressure within the factory interface chamber 108C, or both.

Factory interface environmental control apparatus 118 includes controller 125 including one or more suitable processors, memory, and electronic peripheral components configured and adapted to receive one or more signal inputs from one or more sensors 130 (e.g., relative humidity sensor, oxygen sensor, chemical component sensor, pressure sensor, flow sensor, temperature sensor, and/or the like) and control flow through the one or more valves 122 via a suitable control signal from controller 125.

Controller 125 may execute a closed loop or other suitable control scheme. In some embodiments, the control scheme may change a flow rate of the purge gas being introduced into the factory interface chamber 108C responsive to a measured condition from the one or more sensors 130. In another embodiment, the control scheme may determine when to transfer substrates 245 through the factory interface chamber 108C based upon one or more measured environmental conditions existing within the factory interface chamber 108C.

Factory interface environmental control apparatus 118 may, in one or more embodiments, monitor relative humidity (RH) by sensing any suitable measure of RH in the factory interface chamber 108C. The relative humidity sensor 130 may be configured and adapted to sense relative humidity (RH) in the factory interface chamber 108C. Any suitable type of relative humidity sensor may be used, such as a capacitive-type or other sensor. The RH sensor 130 may be located within the factory interface chamber 108C or within a conduit connected to the factory interface chamber 108C, for example. Controller 125 may monitor RH, and when a measured RH signal value provided to the controller 125 is above a predefined low RH threshold value, carrier doors 216D of the one or more substrate carriers 116 coupled to load ports 115 of the factory interface 108 will stay closed. Likewise, slit valve 223o of the load lock 112 may be kept closed until the measured RH signal level is below the predefined low RH threshold value. Other measures of humidity control may be measured and used as a predefined low RH threshold, such as ppmV of H₂O.

In one or more embodiments, the pre-defined low threshold RH value may be a moisture level less than 1,000 ppmV H₂O, less than 500 ppmV H₂O, less than 100 ppmV H₂O, or even less than 10 ppmV H2O, depending upon the level of moisture that is tolerable for the particular process being carried out on the substrates 245.

The RH level may be lowered by flow of a suitable amount of a purge gas from the purge gas supply 119 into the factory interface chamber 108C. As described herein, the purge gas may be an inert gas from the purge gas supply 119 that may be argon, nitrogen gas (N₂), helium, or mixtures thereof. A supply of dry nitrogen gas (N₂) may be quite effective at controlling environmental conditions within the factory interface chamber 108C. Compressed bulk inert gases having low H₂O levels (as described herein) may be used as the purge gas supply 119. The supplied inert gas from the purge gas supply 119 may fill the factory interface chamber 108C during substrate processing when substrates 245 are being transferred through the factory interface chamber 108C.

In some instances, flow rates of purge gas provided into the factory interface chamber 108C may be monitored by a suitable flow sensor (not shown) on a delivery line and/or pressure sensor located within the factory interface chamber 108C, or both. Flow rates of 400 SLM or more may be provided by adjusting the valve 122 coupled to the purge gas supply 119 responsive to control signals from controller 125. Pressures of less than about 60 kPa may be maintained within the factory interface chamber 108C, for example. Flow of the purge gas (e.g., N2 or other inert gas) into the factory interface chamber 108C can be operative to lower the relative humidity (RH) level within the factory interface chamber 108C. The carrier door 216D and/or the load lock slit valves 223o of the one or more load lock chambers 112A, 112B may be opened when the low RH threshold value is met. This helps to ensure that substrates 245 exiting the substrate carriers 116, exiting the load lock chambers 112A, 112B, as well as any substrates 245 passing through the factory interface chamber 108C are exposed to only a suitably low humidity environment.

In another example, environmental preconditions may be met, for example, when a measured oxygen (O₂) level in the factory interface chamber 108C falls below a predefined level. Oxygen (O₂) level may be sensed by the one or more sensors 130, such as by an oxygen sensor. If the measured oxygen (O₂) level falls below a predefined oxygen threshold level (e.g., less than 50 ppm O₂, less than 10 ppm O₂, less than 5 ppm O₂, or even less than 3 ppm O₂, or even lower), then substrate exchange may take place through the factory interface chamber 108C. Other suitable oxygen level thresholds may be used, depending on the processing taking place. If the predefined oxygen threshold level in the factory interface chamber 108C is not met, the controller 125 will initiate a control signal to the valve 122 coupled to the purge gas supply 119 and flow purge gas into the factory interface chamber 108C until the predefined low oxygen threshold level is met, as determined by the controller 125 receiving signal from O₂ sensor 130.

When the predefined low oxygen threshold level is met, the carrier door 216D and/or the load lock slit valves 223o of the one or more load lock chambers 112A, 112B may be opened. This helps to ensure that substrates 245 exiting the substrate carriers 116, exiting the load lock chambers 112A, 112B, as well as any substrates 245 passing through the factory interface chamber 108C are exposed to relatively low oxygen levels.

In another example, environmental preconditions may be met, for example, when a measured temperature level in the factory interface chamber 108C, such as a temperature of a substrate 245 in the factory interface chamber 108C falls below a predefined temperature threshold level (e.g., less than 100 degrees C., or even lower). In one or more embodiments, the one or more sensors 130 includes a temperature sensor that is configured and adapted to sense a temperature within the factory interface chamber 108C. In some embodiments, the temperature sensor 130 may be placed in close proximity to a path of the substrate 245 as it passes through the factory interface chamber 108C on the load/unload robot 117. In some embodiments, the temperature sensor 130 may be a directional temperature sensor, such as a laser sensor that may be used to determine an extent to which the substrate 245 has been cooled. Once the predefined low temperature threshold level is met, the suitably cool substrate 245 may be loaded into a substrate carrier 116 for transport.

In another example, environmental preconditions may be met, for example, when a measured chemical contaminant level in the factory interface chamber 108C falls below a predefined low threshold level. In one or more embodiments, the one or more sensors 130 may include one or more chemical sensors that are configured and adapted to sense an amount of one or more chemical contaminants (e.g., amines, bases, an amount of one or more volatile organic compound (VOC), or the like) contained within the factory interface chamber 108C. In some embodiments, once a predefined chemical threshold level is met, the substrates 245 may be unloaded from a substrate carrier 116 or otherwise transported through the factory interface chamber 108C.

In the depicted embodiments herein, in addition to the factory interface environmental control apparatus 118, the substrate processing system 100 may further include a filter purge apparatus 103. Filter purge apparatus 103 includes the clean dry air supply 120 coupled to a portion of the factory interface chamber 108C. In particular, the clean dry air supply 120 may include a conduit and one or more valves 121 configured and adapted to control flow of a flushing gas such as clean dry air from the clean dry air supply 120 to a chamber filter 132 housed in the factory interface chamber 108C. The flushing gas comprising clean dry air can be coupled and provided to a plenum chamber 235, which is part of the factory interface chamber 108C and is located at a point upstream from the chamber filter 132. The chamber filter 132 separates the plenum chamber 235 from the portion of the factory interface chamber 108C through which substrates 245 pass.

The chamber filter 132 is configured to filter the purge gas provided to the processing region of the factory interface 108 from the purge gas supply 119. In particular, the chamber filter 132 is a filter that includes the ability to filter very small particulates from the purge gas flow such that any particulates contained in the purge gas supply 119, supply conduits, and/or valves 122 are not exposed to the substrates 245 passing through the factory interface chamber 108C. The chamber filter 132 can be of any suitable construction, and may be a high Efficiency Filtered Air (HEPA) type filter, for example. HEPA filters can remove greater than 99.97% of particles of 0.3 microns in size or larger. However, various different classes of HEPA filters exist with particle filtering capabilities up to 99.9% or higher by the chamber filter 132.

Clean dry air supply 120 (CDA supply) can be the flushing gas and is a supply of air that has a relatively low level of moisture (H₂O) contained therein. CDA supply 120 may be coupled by suitable conduits and one or more valves 121, such as a mass flow controller or an on-off valve, to the factory interface chamber 108C, and in particular to the plenum chamber 235. By one measure, clean dry air is air having a relative humidity level that is less than 10% at room temperature, or even less than 5% at room temperature. By another measure, clean dry air is air having a relative humidity level that has less than 1000 ppmV H₂O, or even less than 100 ppmV H₂O, or even less than 10 ppmV H₂O contained therein in some embodiments. In embodiments, clean dry air (CDA) has a relatively low level of moisture (H₂O) that will not appreciably affect the substrates 245 being transferred through the factory interface chamber 108C.

In more detail, the filter purge apparatus 103 is configured to supply a flushing gas to the chamber filter 132 when the access door 124 is open. Flushing gas can be a different gas than the purge gas in some embodiments. However, in other embodiments both the purge gas and the flushing gas may be the same clean dry air. The flow of the flushing gas can be initiated prior to opening the access door 124 and after terminating the purge gas flow from the purge gas supply 119. The flow of flushing gas from clean dry air supply 120 may continue to flow for the entire time that the access door 124 is open.

Flowing the flushing gas through the chamber filter 132 when the access door 124 is open can reduce contamination of the chamber filter 132 by humidity (moisture) that is contained in the ambient air entering into the factory interface chamber 108C through the access door 124 from the factory environment outside of the factory interface 108. In the depicted embodiment, the flushing gas can be clean dry air from the CDA supply 120. In one or more embodiments, the purge gas can be an inert gas from the purge gas supply 119 and the flushing gas can be clean dry air from the clean dry air supply 120. In one particularly effective embodiment, the purge gas can be an N₂ gas from the purge gas supply 119 and the flushing gas can be clean dry air from the clean dry air supply 120. In other embodiments, the purge gas can be clean dry air and the flushing gas can be clean dry air.

In some embodiments, the access door 124 may include an interlock that allows the access door 124 to be opened only when a suitable environment is contained in the factory interface chamber 108C. For example, the interlock may be opened to allow the access door 124 to be opened after termination of a purge gas flow of inert gas from the purge gas supply 119 and initiation of the flushing gas flow (e.g., a clean and breathable gas) from the CDA supply 120 and when an oxygen sensor 130 that is configured and adapted to sense a level of oxygen (O₂) within or exiting the factory interface chamber 108C measures a value that is above a safe opening threshold value (e.g., a valve above about 20% O₂, for example) that is safe for personnel to be exposed to.

In one embodiment, when personnel seek to enter the factory interface chamber 108C and initiate an entry request, the controller 125 of the factory interface environmental control apparatus 118 may terminate the flow of the purge gas via a control signal to close valve 122 and initiate a flow of clean dry air from the CDA supply 120 via opening valve 121. During this transition, the inert gas environment is exhausted through exhaust 250 and is effectively replaced with clean dry air. Further, during this transition, the valve 340 in return channel 324C is closed. When a level of oxygen detected within the factory interface chamber 108C via sensor 130 reaches a predetermined oxygen level value that has been determined to be safe, the door interlock (e.g., an electromechanical lock) keeping an access door 124 closed may be unlatched to allow the access door 124 to be opened (as shown dotted in FIG. 1) and thus allow the servicing personnel to access to the factory interface chamber 108C for service of one or more components therein. The flow of clean dry air continues the entire time during the servicing.

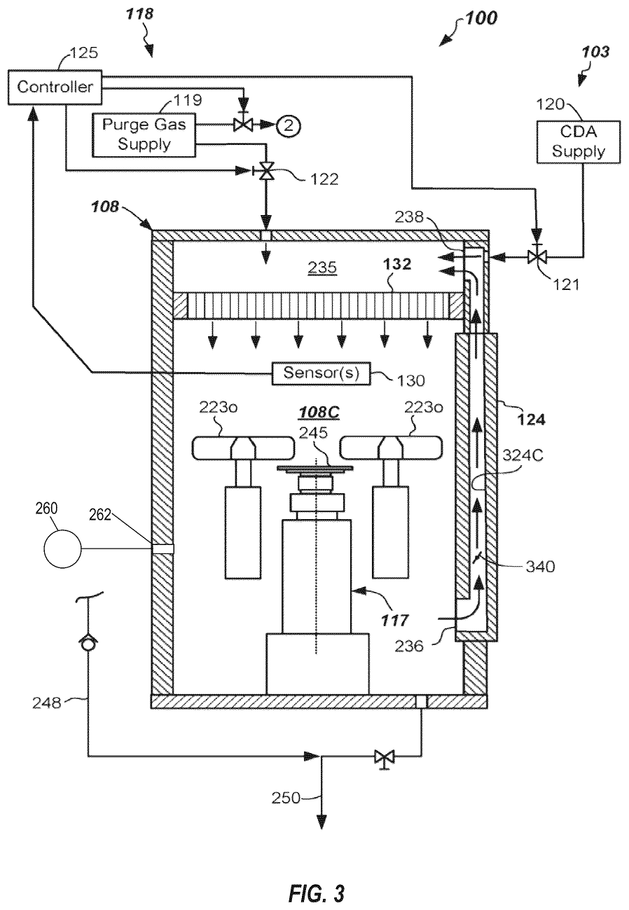

As shown in FIG. 3, a portion of the gas circulation route may be through the access door 124 at times. For example, the purge gas in the initial stages before opening the access door 124 may be into entrance 236 from the factory interface chamber 108C through a return channel 324C (e.g., a duct) formed in the access door 124 and then into the plenum chamber 235 through exit 238. The entrance 236 from the factory interface chamber 108C may be located at or near a bottom of the access door 124, for example.

When the access door 124 is closed (e.g., after servicing), a valve 340 in the return path, such as in return channel 324C, remains closed and the flow of CDA continues but is exhausted from the factory interface chamber 108C through exhaust 250 thus eventually displacing the moist air with the CDA. This flow of clean dry air continues until the atmosphere in the factory interface chamber 108C is again acceptably dry. For example, CDA flow can be ceased and purge gas flow initiated after closure of the access door 124 only after a low threshold level of relative humidity (% RH at RT) is again achieved. Optionally, purge gas from purge gas supply 119 can be initiated as soon as the access door 124 is closed and the purge gas can displace the wet air to the exhaust 250. In this instance, valve 340 is closed until the requisite low threshold of % RH at RT is achieved. After the pre-established low threshold of % RH at RT is achieved, the valve 340 can be opened and the recirculation of the purge gas through return channel 324C can occur.

In the depicted embodiment, the factory interface environmental control apparatus 118 may also include a carrier purge apparatus 218. Carrier purge apparatus 218 provides a flow of purge gas to carrier chambers 241 of the substrate carriers 116. Carrier purge apparatus 218 includes the purge gas supply (e.g., purge gas supply 119) and a plurality of supply conduits 246, 248 and valves coupled thereto. The plurality of supply conduits 246, 248 and valves supply purge gas to the carrier chambers 241 at certain times responsive to control signals from the controller 125. For example, the supply of purge gas may be provided to a carrier chamber 241 from purge gas supply 119 just prior to opening a carrier door 216D of a substrate carrier 116 in order to purge the environment within the substrate carrier 116 to meet certain environmental preconditions. Such environmental preconditions may be met before opening the substrate carrier door 216G allowing the transfer of substrates 245 from the substrate carrier 116 into the factory interface chamber 108C. Carrier purge apparatus 218 may include a set of supply conduits 246, 248 for each substrate carrier 116. Purge gas (e.g., inert gas) may be provided at a suitable flow rate (e.g., 1 standard liter per minute (sim)) to purge the substrate carrier 116. After a suitable purge to control environmental conditions to a desired predefined low level (e.g., of % RH at RT), the carrier door 216D may be opened. The purging of the carrier chamber 241 may take place so that the carrier environment, which may contain undesirable levels of O₂, moisture, particles, or other volatile gases and materials, does not enter into and contaminate the factory interface chamber 108C.

In some embodiments, one or more face clamps 233 (denoted by arrow) may be included to engage the flange of the substrate carrier 116, such as at two or more locations (e.g., around the periphery). Face clamps 233 operate to seal the flange to the front wall 108F, such as to a load port back plate of the front wall 108F. Any suitable face clamping mechanism may be used.

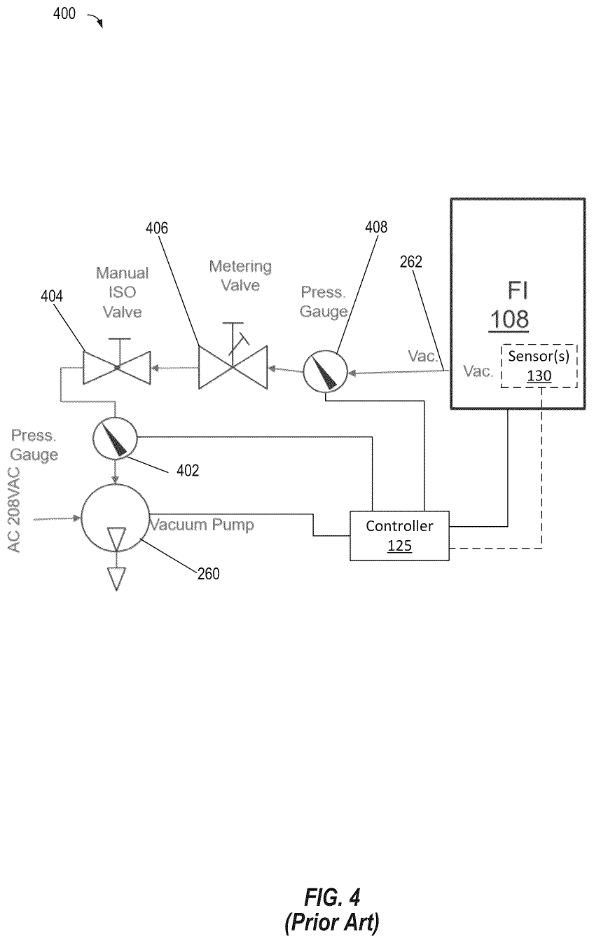

FIG. 4 is a schematic diagram of an example embodiment 400 of a system for providing vacuum to an FI 108 according to previously known techniques. As illustrated, the example embodiment 400 includes a vacuum pump 260, a pressure gauge with pressure switch 402, a controller 125 for the FI, a manual isolation (ISO) valve 404, a metering valve 406, a pressure gauge 408, an FI 108, a vacuum outlet 262 of the FI 108, and zero or more sensor(s) 130 within the FI 108.

In the example embodiment 400, the vacuum pump 260 is operated by a 208-volt alternating current (VAC) electrical supply. The pressure gauge with pressure switch 402 is connected with the inlet side of the vacuum pump 260. The pressure gauge 402 measures the vacuum generated by the vacuum pump 260. The pressure switch included with the pressure gauge 402 can supply an error signal to the controller 125, if the vacuum generated by the vacuum pump 260 is outside of desired values. The manual ISO valve 404 is attached to the inlet side of the vacuum pump 260. The manual ISO valve 404 enables the vacuum pump 260 to be disconnected from the FI 108 for maintenance purposes and other reasons. The metering valve 406 is upstream of the manual ISO valve 404. The metering valve 406 may be set to control the pressure of the vacuum provided to the FI 108 and the flow rate of gases being removed from the FI 108. The pressure gauge 408 is upstream of the metering valve 406. The pressure gauge 408 supplies measurements of the vacuum being generated in the vacuum outlet 262. The metering valve 406 may be set (e.g., by an operator of the system or by a controller of the processing system), to control the vacuum in the vacuum outlet 262 and provided to the FI 108, based on the measurements of the vacuum in the vacuum outlet 262. Optionally, the controller 125 may control the provision of the vacuum to the FI 108 based on signals (e.g., indications of measurements, robot arm positions, or door positions) supplied by sensor(s) 130 within the FI 108.

The table below shows a set of desirable utility connections for an FI, according to previously known techniques:

Utility Connections:

| | |
|---|---|
| Electrical power | DC 24 V, 5 A Maximum |
| Compressed air | Max. 0.8 MPa (120 psi) (pressure relative) |
| (input) | Min. 0.34 MPa (50 psi) (pressure relative) |
| | Oil-free |
| Vacuum (input) | <60 kPa, 10 L/min |
| Exhaust (output) | One-touch fittings for ¼″ tubing (CDA) |
| Connections | One-touch fittings for ¼″ tubing (CDA) |
| | One-touch fittings for ¼″ tubing (vacuum) |

As shown by the table above, previously known FIs may utilize both an input line for supplying CDA to the FI and a vacuum line for supplying vacuum to the FI.

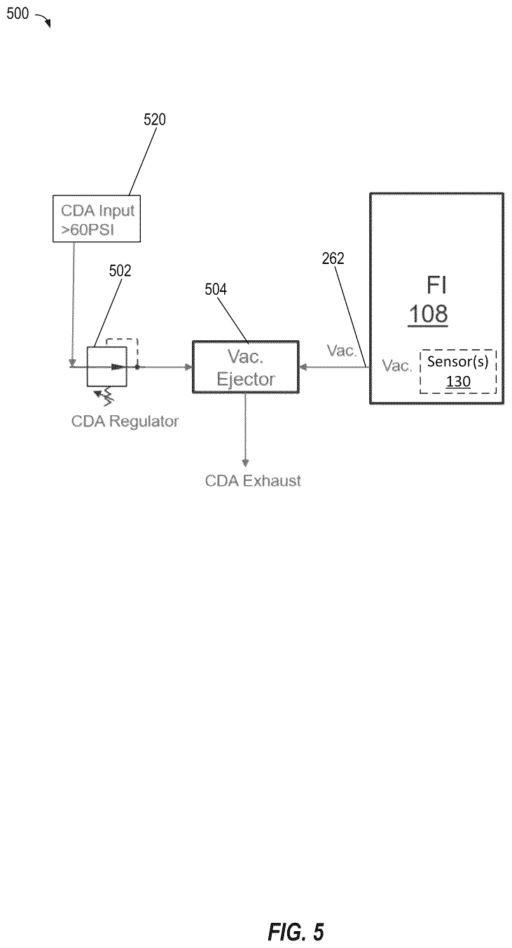

FIG. 5 illustrates a schematic diagram of an example embodiment 500 of a system for providing vacuum to an FI 108, according to one or more embodiments of the present disclosure. As illustrated, the example embodiment 500 includes a vacuum ejector (vac. ejector) 504, a CDA regulator 502, an FI 108, a vacuum outlet 262 of the FI 108, a CDA input 520, and zero or more sensor(s) 130 within the FI 108.

In the example embodiment 500, the vacuum ejector 504 is operated by CDA. The inlet side of the vacuum ejector 504 is connected to the vacuum outlet 262 of the FI 108 to provide vacuum to the FI 108. The vacuum ejector 504 is equipped with a pressure gauge and/or other sensor (e.g., a pressure switch) that supplies measurements or other indications of the pressure of the vacuum generated by vacuum ejector 504. The CDA input 520 supplies CDA at a pressure of 60 psi or higher. The CDA regulator 502 controls the flow rate and/or pressure of CDA supplied from the CDA input 520 to the vacuum ejector 504, thus controlling the generation of vacuum by the vacuum ejector 504. The CDA regulator 502 may be set or controlled (e.g., by an operator or a controller, such as the controller 125 of FIGS. 1-3) to enable control of the vacuum provided to the FI 108. The CDA regulator 502 and the vacuum ejector 504 may be set and/or configured based on the measurements supplied by the pressure gauge of the vacuum ejector 504. The CDA input 520 may be an example of the CDA supply 120 shown in FIGS. 1-3. Optionally, control (e.g., by an operator or a controller, such as the controller 125 of FIGS. 1-3) of the CDA input 520, the CDA regulator 502, and the vacuum ejector 504 may be based on signals (e.g., indications of measurements, robot arm positions, or door positions) supplied by one or more sensor(s) 130 in the FI 108.

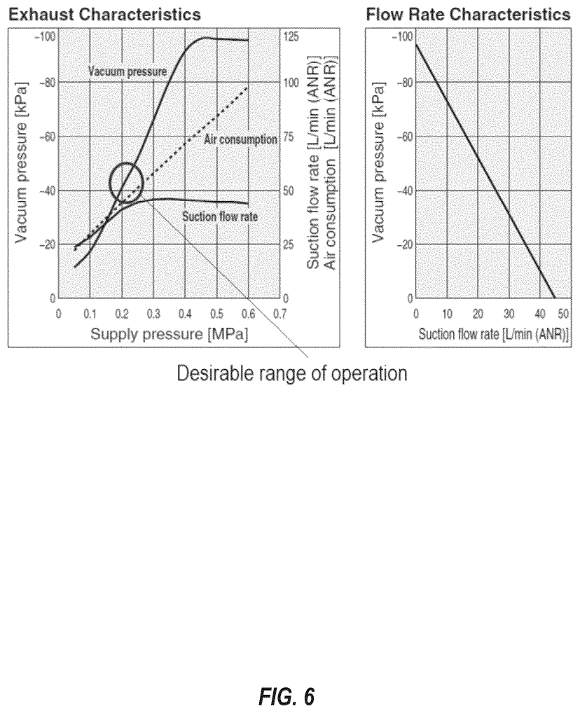

FIG. 6 illustrates two graphs of performance of an example vacuum ejector, such as the vacuum ejector 504 shown in FIG. 5, in accordance with an embodiment of the present disclosure. As illustrated, the example vacuum ejector is capable of developing a negative gauge pressure stronger than −40 kPa when supplied CDA at a pressure of 0.2 to 0.3 MPa. When the example vacuum ejector is supplied CDA at a pressure of 0.2 to 0.3 MPa and connected to an FI such as FI 108 shown in FIGS. 1-5, the example vacuum ejector can provide the vacuum with a negative gauge pressure of −40 kPa, i.e., the vacuum is provided at approximately 60 kPa absolute pressure. When the example vacuum ejector is operated to develop a vacuum pressure of approximately −40 kPa, the example vacuum ejector has a suction flow rate of approximately 25 L/min, meeting or exceeding the vacuum pressure and flow rate listed in the table of desirable utility connections shown above. By regulating CDA input pressure to the vacuum ejector 504 using CDA regulator 502, a desired vacuum may be provided to the FI 108. It may be noted that a greater negative pressure causes a decrease in the suction flow of the example vacuum ejector. In cases where a higher suction flow with a greater negative pressure is desired, a different vacuum ejector may be used.

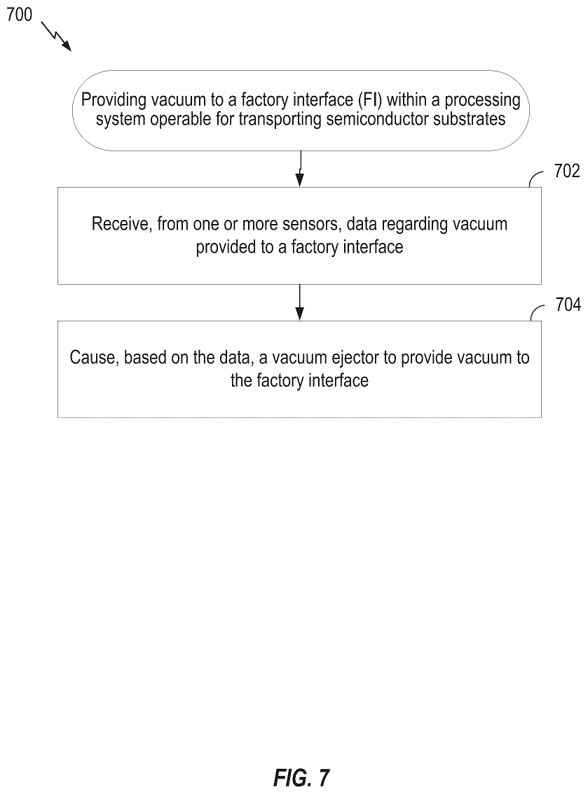

FIG. 7 is a flowchart of a method 700 for providing vacuum to a factory interface within a processing system operable for transporting semiconductor substrates, such as FI 108 described in this disclosure. An operator or a controller (e.g., the controller 125 of FIGS. 1-3) may control each operation of the method.

Operation 702 includes receiving, from one or more sensors, data regarding vacuum provided to the factory interface. For example and with reference to FIG. 5, an operator or a controller (e.g., the controller 125 of FIGS. 1-3) may receive, from the sensor (e.g., the pressure gauge, sensor and/or pressure switch) within vacuum ejector 504, data regarding a pressure of vacuum provided by the vacuum ejector 504 to FI 108.

Operation 704 includes causing, based on the data, a vacuum ejector to provide vacuum to the factory interface. Continuing the example from above, an operator or a controller (e.g., the controller 125 from FIGS. 1-3) causes the vacuum ejector 504 to provide vacuum to the FI 108.

In some embodiments, causing the vacuum ejector to provide the vacuum includes causing clean dry air (CDA) to flow to the vacuum ejector.

In some embodiments, causing the vacuum ejector to provide the vacuum includes causing a regulator (e.g., CDA regulator 502) to change a flow rate of CDA to the vacuum ejector.

In one embodiment, causing the vacuum ejector to provide the vacuum includes causing CDA at a pressure between approximately 200 kilopascals (kPa) and 250 kPa to flow to the vacuum ejector. Causing CDA to flow to the vacuum ejector can include causing the CDA to flow at a flow rate between approximately 35 liters/minute (L/min) and 60 L/min.

In some embodiments, a system for transporting semiconductor substrates may include an FI (e.g., FI 108), one or more robots (e.g., load/unload robot 117) disposed within the FI, and a vacuum ejector (e.g., vacuum ejector 504) operable to provide vacuum to the FI.

In some embodiments, the system for transporting semiconductor substrates further includes a controller (e.g., controller 125) configured to control operation of the vacuum ejector.

In some embodiments, the system for transporting semiconductor substrates further includes a CDA regulator (e.g., CDA regulator 502) operable to control a flow rate of CDA to the vacuum ejector. In some embodiments, the controller is configured to control the operation of the vacuum ejector by controlling operation of the CDA regulator.

In some embodiments, the vacuum ejector is operable to provide the vacuum to the FI in response to a flow of CDA to the vacuum ejector. In one embodiment, the flow of CDA is at a pressure between approximately 200 kilopascals (kPa) and 250 kPa. In one embodiment, the flow of CDA is at a flow rate between approximately 35 liters/minute (L/min) and 60 L/min.

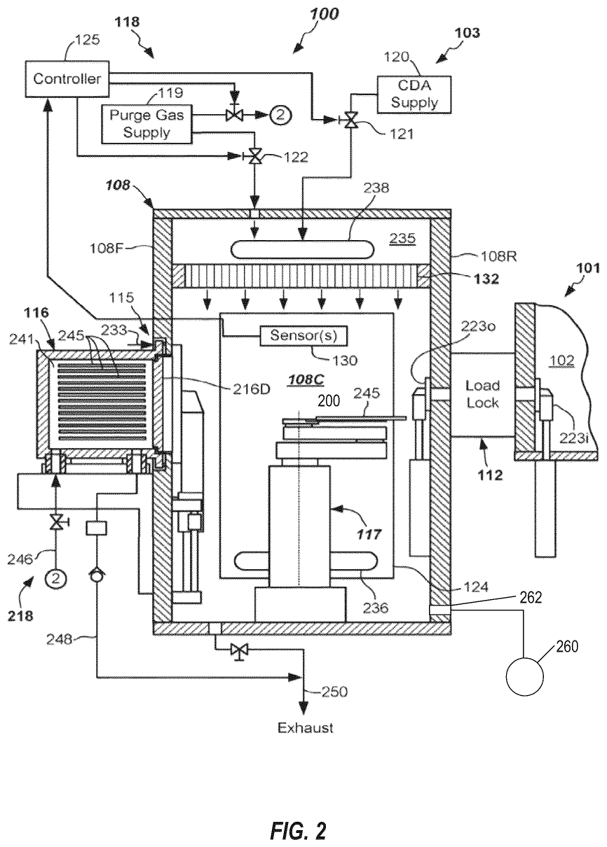

In some embodiments, the system for transporting semiconductor substrates further includes a load lock (e.g., load locks 112, shown in FIGS. 1-2), a door (e.g., doors of slit valves 223o, shown in FIGS. 2-3), and a vacuum pump (e.g., vacuum pump 260, shown in FIGS. 2-4). The door is operable to open and close. An interior of the load lock and the interior of the FI are in fluidic communication while the door is open. The interior of the load lock is fluidically isolated from the interior of the FI while the door is closed. The vacuum pump is operable to remove gas from the interior of the load lock. The FI is fluidically isolated from the vacuum pump while the door is closed.

In some embodiments, a system for transporting substrates includes an FI (e.g., FI 108, shown in FIGS. 1-5), a first robot (e.g., load/unload robot 117 shown in FIGS. 1-3), a sensor (e.g., sensor(s) 130, shown in FIGS. 1-5), a vacuum ejector (e.g., vacuum ejector 504, shown in FIG. 5), a source of CDA (e.g., CDA supply 120, shown in FIGS. 1-3, or CDA input 520, shown in FIG. 5), a CDA regulator (e.g., CDA regulator 502, shown in FIG. 5), a load lock (e.g., load lock chamber 112A, shown in FIG. 1), a first door (e.g., door of slit valve 223o of load lock chamber 112A, shown in FIG. 1), a vacuum pump (e.g., vacuum pump 260, shown in FIGS. 2-4), a transfer chamber (e.g., transfer chamber 102, shown in FIGS. 1-2), a second robot (e.g., transfer robot 104, shown in FIG. 1), one or more processing chambers (e.g., processing chambers 106, shown in FIG. 1), and a controller (e.g., controller 125, shown in FIGS. 1-4). The vacuum ejector is operable to provide vacuum to the FI. The CDA regulator is operable to control a flow of the CDA from the source to the vacuum ejector. The first door is operable to open and close. An interior of the load lock and the interior of the FI are in fluidic communication while the first door is open. The interior of the load lock is fluidically isolated from the interior of the FI while the first door is closed. The vacuum pump is operable to remove gas from the interior of the load lock. The interior of the FI is fluidically isolated from the vacuum pump while the first door is closed. The second robot is disposed within the transfer chamber. The sensor is operable to generate a signal based on a condition associated with the FI. The controller is configured to cause the first robot to receive a carrier with a substrate thereon from one of the load ports. The controller is further configured to cause the vacuum ejector to provide vacuum to the FI after the first robot receives the carrier with the substrate. The controller is further configured to cause the first door to open after the vacuum ejector provides vacuum to the FI. The controller is further configured to cause the first robot to place the carrier with the substrate into the load lock while the first door is open. The controller is further configured to cause the first door to close after the first robot places the carrier with the substrate into the load lock. The controller is further configured to cause the vacuum pump to remove gas from the load lock after the first door closes.

In some embodiments, the controller is configured to cause the CDA regulator to supply the CDA to the vacuum ejector at a pressure between approximately 200 kilopascals (kPa) and 250 kPa.

In some embodiments, the controller is configured to cause the CDA regulator to supply the CDA to the vacuum ejector at a flow rate between approximately 35 liters/minute (L/min) and 60 L/min.

In some embodiments, the controller is configured to further cause the first robot receive the carrier from a front opening unified pod (FOUP) connected with the one of the load ports.

In some embodiments, the system for transporting substrates further includes a second door (e.g., doors of slit valves 223i, shown in FIG. 2). The second door is operable to open and close. The interior of the load lock and an interior of the transfer chamber are in fluidic communication while the second door is open. The interior of the load lock is fluidically isolated from the interior of the transfer chamber while the second door is closed. The controller is configured to further cause the second door to close before causing the first door to open. The controller is configured to further cause the second door to open after the vacuum pump removes the gas from the interior of the load lock. The controller is configured to further cause the second robot to remove the carrier with the substrate from the load lock while the second door is open after the vacuum pump removes the gas from the load lock.

In some embodiments, the system for transporting substrates further includes another load lock (e.g., load lock chamber 112B, shown in FIG. 1) and a second door (e.g. door of slit valve 223o of load lock chamber 112B, shown in FIG. 1). The second door is operable to open and close. An interior of the other load lock and the interior of the FI are in fluidic communication while the second door is open. The interior of the other load lock is fluidically isolated from the interior of the FI while the second door is closed. The controller is configured to further cause the vacuum ejector to provide vacuum to the FI in response to the second robot placing another carrier with another substrate thereon into the other load lock. The controller is configured to further cause the second door to open after the vacuum ejector provides vacuum to the FI. The controller is configured to further cause the first robot to remove the other carrier with the other substrate from the other load lock while the second door is open. The controller is configured to further cause the first robot to place the other carrier with the other substrate into one of the load ports. The controller is configured to further cause the second door to close after the second robot removes the other carrier with the other substrate from the other load lock.

In one embodiment, the vacuum pump is operable to remove gas from the other load lock.

While the foregoing is directed to embodiments of the present disclosure, other and further embodiments of the disclosure may be devised without departing from the basic scope thereof, and the scope thereof is determined by the claims that follow.

What is claimed is:

1. A method for providing vacuum to a factory interface within a processing system operable for transporting semiconductor substrates, comprising:
receiving, from one or more sensors, data regarding vacuum provided to the factory interface; and
causing, based on the data, a vacuum ejector to provide vacuum to the factory interface.

2. The method of claim 1, wherein causing the vacuum ejector to provide the vacuum comprises causing clean dry air (CDA) to flow to the vacuum ejector.

3. The method of claim 1, wherein causing the vacuum ejector to provide the vacuum comprises causing a regulator to change a flow rate of clean dry air (CDA) to the vacuum ejector.

4. The method of claim 1, wherein causing the vacuum ejector to provide the vacuum comprises causing clean dry air (CDA) at a pressure between approximately 200 kilopascals (kPa) and 250 kPa to flow to the vacuum ejector.

5. The method of claim 4, wherein causing CDA to flow to the vacuum ejector comprises causing the CDA to flow at a flow rate between approximately 35 liters/minute (L/min) and 60 L/min.

6. The method of claim 1, further comprising:
causing a carrier with a substrate disposed thereon to move from a front opening unified pod (FOUP) to an interior of the factory interface prior to causing the vacuum ejector to provide the vacuum to the factory interface; and
causing the carrier with the substrate to move from the interior of the factory interface into a load lock subsequent to causing the vacuum ejector to provide the vacuum to the factory interface.

7. A system operable for transporting semiconductor substrates, comprising:
a factory interface;
one or more robots disposed within the factory interface; and
a vacuum ejector operable to provide vacuum to the factory interface.

8. The system of claim 7, further comprising a controller configured to control operation of the vacuum ejector.

9. The system of claim 7, further comprising a clean dry air (CDA) regulator operable to control a flow rate of CDA to the vacuum ejector.

10. The system of claim 7, wherein the vacuum ejector is operable to provide the vacuum to the factory interface in response to a flow of clean dry air (CDA) to the vacuum ejector.

11. The system of claim 10, wherein the flow of CDA is at a pressure between approximately 200 kilopascals (kPa) and 250 kPa.

12. The system of claim 10, wherein the flow of CDA is at a flow rate between approximately 35 liters/minute (L/min) and 60 L/min.

13. The system of claim 7, further comprising:
a load lock;
a door operable to open and close, wherein an interior of the load lock and the interior of the factory interface are in fluidic communication while the door is open, and wherein the interior of the load lock is fluidically isolated from the interior of the factory interface while the door is closed; and
a vacuum pump operable to remove gas from the interior of the load lock, wherein the factory interface is fluidically isolated from the vacuum pump while the door is closed.

14. A system operable for transporting substrates, comprising:
a factory interface (FI) having one or more load ports;
a first robot disposed within the FI;
a sensor operable to generate a signal based on a condition associated with the FI;
a vacuum ejector operable to provide vacuum to the FI;
a source of clean dry air (CDA);
a CDA regulator operable to control a flow of the CDA from the source to the vacuum ejector;
a load lock;
a first door operable to open and close, wherein an interior of the load lock and the interior of the FI are in fluidic communication while the first door is open, and wherein the interior of the load lock is fluidically isolated from the interior of the FI while the first door is closed;
a vacuum pump operable to remove gas from the interior of the load lock, wherein the interior of the FI is fluidically isolated from the vacuum pump while the first door is closed;
a transfer chamber;
a second robot disposed within the transfer chamber;
one or more processing chambers; and
a controller configured to:
cause the first robot to receive a carrier with a substrate thereon from one of the load ports;
cause the vacuum ejector to provide vacuum to the FI after the first robot receives the carrier with the substrate;
cause the first door to open after the vacuum ejector provides vacuum to the FI;
cause the first robot to place the carrier with the substrate into the load lock while the first door is open;
cause the first door to close after the first robot places the carrier with the substrate into the load lock; and
cause the vacuum pump to remove gas from the load lock after the first door closes.

15. The system of claim 14, wherein the controller is configured to cause the CDA regulator to supply the CDA to the vacuum ejector at a pressure between approximately 200 kilopascals (kPa) and 250 kPa.

16. The system of claim 14, wherein the controller is configured to cause the CDA regulator to supply the CDA to the vacuum ejector at a flow rate between approximately 35 liters/minute (L/min) and 60 L/min.

17. The system of claim 14, wherein the controller is configured to further cause the first robot receive the carrier from a front opening unified pod (FOUP) connected with the one of the load ports.

18. The system of claim 14, further comprising a second door operable to open and close, wherein the interior of the load lock and an interior of the transfer chamber are in fluidic communication while the second door is open, and wherein the interior of the load lock is fluidically isolated from the interior of the transfer chamber while the second door is closed, wherein the controller is configured to cause the second door to close before causing the first door to open, wherein the controller is configured to cause the second door to open after the vacuum pump removes the gas from the interior of the load lock, and wherein the controller is configured to cause the second robot to remove the carrier with the substrate from the load lock while the second door is open after the vacuum pump removes the gas from the load lock.

19. The system of claim 14, further comprising:
another load lock; and
a second door operable to open and close, wherein an interior of the other load lock and the interior of the FI are in fluidic communication while the second door is open, and wherein the interior of the other load lock is fluidically isolated from the interior of the FI while the second door is closed, wherein the controller is configured to:
cause the vacuum ejector to provide vacuum to the FI in response to the second robot placing another carrier with another substrate thereon into the other load lock;
cause the second door to open after the vacuum ejector provides vacuum to the FI;
cause the first robot to remove the other carrier with the other substrate from the other load lock while the second door is open;
cause the first robot to place the other carrier with the other substrate into one of the load ports; and
cause the second door to close after the second robot removes the other carrier with the other substrate from the other load lock.

20. The system of claim 19, wherein the vacuum pump is operable to remove gas from the other load lock.
